(19) United States
(12) Patent Application Publication
(10) Pub. No.: US 2026/0314201 A1
(43) Pub. Date: Oct. 8, 2026

(54) DISPLAY DEVICE AND ELECTRONIC DEVICE INCLUDING THE SAME

(71) Applicant: Samsung Display Co., Ltd., Yongin-si (KR)

(72) Inventors: Kyungsu Lee, Yongin-si (KR); Deokjung Kim, Yongin-si (KR); Inyoung Han, Yongin-si (KR)

(21) Appl. No.: 19/576,946

(22) Filed: Mar. 24, 2026

(30) Foreign Application Priority Data
Apr. 4, 2025 (KR) 10-2025-0044279

(51) Int. Cl. H10K 59/131; H10K 59/40

(52) U.S. Cl. CPC H10K 59/131; H10K 59/40

(57) ABSTRACT

A display device includes a display panel including a display portion, and a touch sensor portion above the display portion, and a driver configured to drive the display portion and the touch sensor portion, wherein the display portion includes a light-emitting diode, a first power voltage line configured to supply a first power voltage to the light-emitting diode, and a second power voltage line configured to supply a second power voltage to the light-emitting diode, wherein the touch sensor portion includes a touch electrode, and a touch-electrode-connecting line electrically connecting the touch electrode with the driver, and including a first connection wire connected to the driver, a second connection wire above the first connection wire, and connected to the first connection wire, and a third connection wire above the first power voltage line and the second connection wire, and connecting the second connection wire with the touch electrode.

### CROSS-REFERENCE TO RELATED APPLICATION

The present application claims priority to, and the benefit of Korean Patent Application No. 10-2025-0044279, filed on Apr. 4, 2025, in the Korean Intellectual Property Office, the entire disclosure of which is incorporated herein by reference.

### BACKGROUND

### 1. Field

One or more embodiments relate to a display device, and an electronic device including the display device.

### 2. Description of the Related Art

Mobility-based electronic devices are in wide use. As well as compact electronic devices, such as mobile phones, tablet personal computers (PCs), have also recently been widely used as mobile electronic devices.

To support various functions, such mobile electronic devices include a display device to provide users with visual information, such as images or videos. Recently, as other components for driving a display device are miniaturized, the proportion occupied by the display device in an electronic device has been gradually increased, and structures to enable bending of the display device from a flat state to a certain angle are under development.

### SUMMARY

One or more embodiments include a display device in which unnecessary resistance in a touch sensor portion is reduced and noise generated in a display portion is reduced so less noise is transmitted to the touch sensor portion.

However, such an aspect is an example, and the aspects of the disclosure are not limited thereto.

Additional aspects will be set forth in part in the description which follows and, in part, will be apparent from the description, or may be learned by practice of the presented embodiments of the disclosure.

According to one or more embodiments, a display device includes a display panel including a display portion, and a touch sensor portion above the display portion, and a driver configured to drive the display portion and the touch sensor portion, wherein the display portion includes a light-emitting diode, a first power voltage line configured to supply a first power voltage to the light-emitting diode, and a second power voltage line configured to supply a second power voltage to the light-emitting diode, wherein the touch sensor portion includes a touch electrode, and a touch-electrode-connecting line electrically connecting the touch electrode with the driver, and including a first connection wire connected to the driver, a second connection wire above the first connection wire, and connected to the first connection wire, and a third connection wire above the first power voltage line and the second connection wire, and connecting the second connection wire with the touch electrode.

The first power voltage line may include a first-1 power voltage line at a same layer as the second connection wire, and spaced apart from the second connection wire, and a first-2 power voltage line above the first-1 power voltage line and electrically connected to the first-1 power voltage line.

The third connection wire may be above the first-2 power voltage line, and has a portion overlapping the first power voltage line.

The first-2 power voltage line may define a first opening, wherein the third connection wire is connected to the second connection wire through the first opening.

The second power voltage line may include a second-1 power voltage line at a same layer as the second connection wire, and spaced apart from the second connection wire, and a second-2 power voltage line above the second-1 power voltage line and electrically connected to the second-1 power voltage line.

The second-1 power voltage line may include a shield portion at least partially overlapping the first connection wire.

The display portion may further include a signal line configured to supply at least one of a scan signal or a data signal to the light-emitting diode, at a same layer as the second-2 power voltage line, and having a portion overlapping the shield portion.

A portion of the second-2 power voltage line may overlap the second connection wire.

The display portion may further include a semiconductor layer, a gate electrode above the semiconductor layer, a source electrode and a drain electrode at a layer above the gate electrode, and electrically connected to the semiconductor layer, and a first connecting electrode at a layer above the source electrode and the drain electrode, and electrically connecting the source electrode or the drain electrode with the light-emitting diode.

The gate electrode and the first connection wire may include a same material, and are at a same layer, wherein the source electrode, the drain electrode, and the second connection wire include a same material, and are at a same layer.

According to one or more embodiments, an electronic device includes a display panel including a display portion, and a touch sensor portion above the display portion, and a driver configured to drive the display portion and the touch sensor portion, wherein the display portion includes a semiconductor layer, a gate electrode above the semiconductor layer, a source electrode and a drain electrode at a layer above the gate electrode, and electrically connected to the semiconductor layer, a first connecting electrode at a layer above the source electrode and the drain electrode, and electrically connected to the source electrode or the drain electrode, a light-emitting diode above the first connecting electrode, and electrically connected to the first connecting electrode, a first power voltage line configured to supply a first power voltage to the light-emitting diode, and a second power voltage line configured to supply a second power voltage to the light-emitting diode, wherein the touch sensor portion includes a touch electrode, and a touch-electrode-connecting line electrically connecting the touch electrode with the driver, and including a first connection wire connected to the driver and at a same layer as the gate electrode, a second connection wire connected to the first connection wire and at a same layer as the source electrode and the drain electrode, and a third connection wire above the second connection wire and connecting the second connection wire with the touch electrode.

The third connection wire may be above the first power voltage line and the second power voltage line.

The first power voltage line may include a first-1 power voltage line at a same layer as the second connection wire and spaced apart from the second connection wire, and a first-2 power voltage line above the first-1 power voltage line and electrically connected to the first-1 power voltage line.

The third connection wire may be above the first-2 power voltage line, wherein a portion of the third connection wire overlaps the first power voltage line.

The first-2 power voltage line may define a first opening overlapping the second connection wire.

The third connection wire may be connected to the second connection wire through the first opening.

The second power voltage line may include a second-1 power voltage line at a same layer as the second connection wire, and spaced apart from the second connection wire, and a second-2 power voltage line above the second-1 power voltage line and electrically connected to the second-1 power voltage line.

The second-1 power voltage line may include a shield portion at least partially overlapping the first connection wire.

The display portion may further include a signal line configured to supply at least one of a scan signal or a data signal to the light-emitting diode, at a same layer as the second-2 power voltage line, and having a portion overlapping the shield portion.

A portion of the second-2 power voltage line may overlap the second connection wire.

Aspects other than those described above will become apparent from the following drawings, claims, and detailed description of the disclosure.

### BRIEF DESCRIPTION OF THE DRAWINGS

The above and other aspects of embodiments of the disclosure will be more apparent from the following description taken in conjunction with the accompanying drawings, in which:

FIG. 1 is a plan view schematically illustrating a display device according to one or more embodiments;

FIG. 2 is a block diagram schematically illustrating a display device according to one or more embodiments;

FIG. 3 is a plan view schematically illustrating a display device according to one or more embodiments;

FIG. 4 is a plan view schematically illustrating a touch sensor portion according to one or more embodiments;

FIG. 5 is a circuit diagram schematically illustrating a sensor driver according to one or more embodiments;

FIG. 6 is a cross-sectional view schematically illustrating a display device according to one or more embodiments;

FIG. 7 is a plan view schematically illustrating a display device according to one or more embodiments;

FIG. 8 is a cross-sectional view schematically illustrating a display device according to one or more embodiments;

FIG. 9 is a plan view schematically illustrating a display device according to one or more embodiments;

FIG. 10 is a cross-sectional view schematically illustrating a display device according to one or more embodiments;

FIG. 11 is a plan view schematically illustrating a display device according to one or more embodiments;

FIG. 12 is a cross-sectional view schematically illustrating a display device according to one or more embodiments;

FIG. 13 is a plan view schematically illustrating a display device according to one or more embodiments;

FIG. 14 is a cross-sectional view schematically illustrating a display device according to one or more embodiments;

FIG. 15 is a plan view schematically illustrating a display device according to one or more embodiments;

FIG. 16 is a plan view schematically illustrating a display device according to one or more embodiments;

FIG. 17 is a plan view schematically illustrating a display device according to one or more embodiments;

FIG. 18 is a cross-sectional view schematically illustrating a display device according to one or more embodiments;

FIG. 19 is a plan view schematically illustrating a display device according to one or more embodiments;

FIG. 20 is a cross-sectional view schematically illustrating a display device according to one or more embodiments;

FIG. 21 is a plan view schematically illustrating a display device according to one or more embodiments;

FIG. 22 is a cross-sectional view schematically illustrating a display device according to one or more embodiments;

FIG. 23 is a block diagram schematically illustrating an electronic device according to one or more embodiments; and

FIG. 24 is a perspective view schematically illustrating an electronic device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

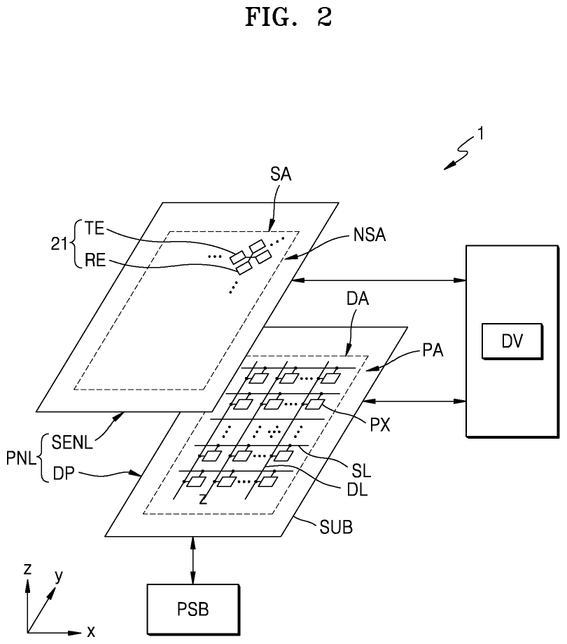

In the specification, a “plan view” refers to a two-dimensional view seen in a direction perpendicular to a substrate SUB (see FIG. 2). That is, “A and B spaced apart from each other in a plan view” means “A and B spaced apart from each other when viewed in a direction perpendicular to the substrate SUB (see FIG. 2).”

In the specification, a “cross-sectional view” refers to a two-dimensional view cut in a direction perpendicular to the substrate SUB (see FIG. 2). That is, “A and B spaced apart from each other in a cross-sectional view” means “A and B spaced apart from each other in a two-dimensional view cut in a direction perpendicular to the substrate SUB (see FIG. 2).”

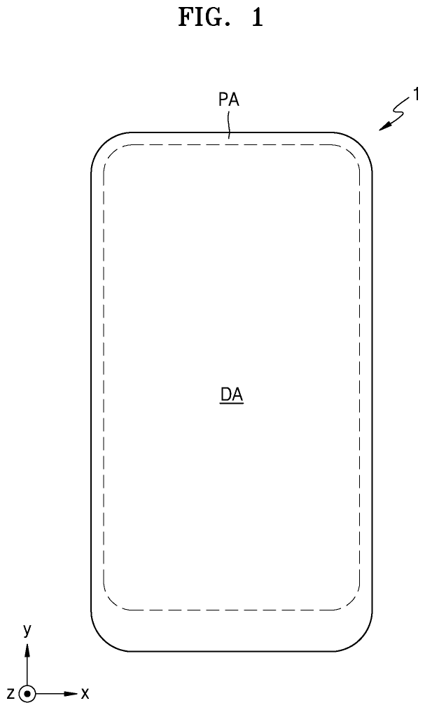

FIG. 1 is a plan view schematically illustrating a display device 1 according to one or more embodiments.

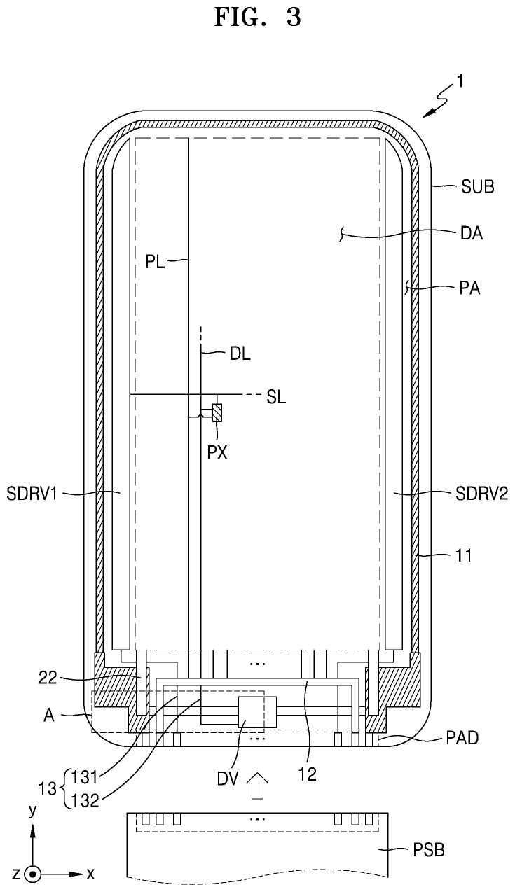

Referring to FIG. 1, the display device 1 includes a display area DA, and a peripheral area PA outside of and/or at a periphery of the display area DA. Because the display device 1 includes the substrate SUB (see FIG. 3), it may be understood that the substrate SUB (see FIG. 3) includes the display area DA and the peripheral area PA. Alternatively, it may be understood that the display area DA and the peripheral area PA are defined on the substrate SUB.

The display area DA is a portion that displays the image, and multiple pixels may be located in the display area DA. The display area DA may have various shapes, such as a circle, an ellipse, a polygon, or a shape of a corresponding shape. In FIG. 1, the display area DA is illustrated as having a roughly rectangular shape with rounded corners.

The peripheral area PA may be located outside the display area DA. The peripheral area PA may surround at least a portion of the display area DA (e.g., in plan view).

Hereinafter, an organic light-emitting display device will be used as an example as the display device 1 according to one or more embodiments of the present disclosure, but the display device of the disclosure is not limited thereto. In one or more other embodiments, the display device 1 may include an inorganic light-emitting display device, an inorganic electroluminescent (EL) display device, or a quantum-dot light-emitting display device. For example, an emission layer of a display element provided in the display device 1 may include an organic material, an inorganic material, quantum dots, a combination of an organic material and quantum dots, or a combination of an inorganic material and quantum dots.

FIG. 2 is a block diagram schematically illustrating the display device 1 according to one or more embodiments.

Referring to FIG. 2, the display device 1 may include a display panel PNL, a driver DV, and a printed circuit board PSB.

The display panel PNL may include a display portion DP for displaying the images and a touch sensor portion SENL for detecting touch or pressure input. For example, the touch sensor portion SENL may obtain information about the user's touch input. The touch sensor portion SENL may include a touch sensor and a fingerprint sensor.

The display panel PNL may include the pixels PX and touch electrodes 21. In one or more embodiments, the pixels PX may display images in display frame period units. The touch electrodes 21 may sense a user's input (e.g., touch input) in sensing frame period units. The sensing frame period and the display frame period may be independent of each other or may be different from each other. The sensing frame period and the display frame period may be synchronous or asynchronous.

A touch sensor portion SENL including the touch electrodes 21 may obtain information about the user's touch input. According to one or more embodiments (e.g., mutual capacitance method), the touch electrodes 21 may include a driving electrode TE and a detection electrode RE. For example, the driving electrode TE may be a Tx (transmitter) pattern, and the detection electrode RE may be an Rx (receiver) pattern. Information about a touch input (or touch event) may include information, such as the location of the touch that the user intends to provide.

In FIG. 2, the touch sensor portion SENL is illustrated as being located on the front side of the display portion DP (e.g., the upper surface where the images is displayed), but the location of the touch sensor portion SENL are not limited thereto. For example, the touch sensor portion SENL may be located on a back side or both sides of the display portion DP. Alternatively, the touch sensor portion SENL may be located on at least one edge area of the display portion DP.

The display portion DP may include the substrate SUB and the pixels PX provided on the substrate SUB. The pixels PX may be located in the display area DA. Scan lines SL and data lines DL, and the pixels PX connected to the scan lines SL and the data lines DL may be located in the display area DA. The pixels PX may be selected by scan signals of a turn-on level supplied from the scan lines SL, pixels PX may receive data signals from the data lines DL, and pixels PX may emit light of a brightness corresponding to the data signals. Accordingly, the images corresponding to the data signals may be displayed in the display area DA. However, the structure and driving method of the pixels PX are not particularly limited thereto. For example, each of the pixels PX may have a variety of structures, and each of the pixels PX may be implemented using various driving methods.

Various lines and/or circuits connected to the pixels PX of the display area DA may be located in the peripheral area PA. For example, a plurality of lines may be located in the peripheral area PA to supply various power and control signals to the display area DA.

The touch sensor portion SENL may include the plurality of touch electrodes 21. The touch electrodes 21 may be located in a detection area SA. The touch sensor portion SENL may include the detection area SA, and a non-detection area NSA located outside the detection area SA. The detection area SA may be set as an area that may respond to touch input (e.g., the active area of the sensor).

The detection area SA may overlap at least one area of the display area DA. For example, the detection area SA may be set as an area corresponding to the display area DA (e.g., an area overlapping the display area DA), and the non-detection area NSA may be set as an area corresponding to the peripheral area PA (e.g., an area overlapping the peripheral area PA). In this case, when the touch input, etc. is provided on the display area DA, the touch input may be detected through the touch sensor portion SENL.

The driver DV generates the data signals, and the generated the data signals may be transmitted to the data lines DL. The data signals may be sequentially transmitted to the pixels PX located in the same column through data lines DL extended in a second direction (e.g., a y-axis direction). Additionally, the driver may generate a touch-driving signal that is transmitted to each of the touch electrodes 21 of the touch sensor portion SENL.

That is, the driver DV may be a touch display driver integration (TDDI) IC that integrates the display portion DP driving function and the touch sensor portion SENL sensing function into a single chip. In this case, because the driving function and the sensing function are performed simultaneously with a single TDDI chip, noise information generated from the display portion DP may be controlled, thereby securing improved noise performance.

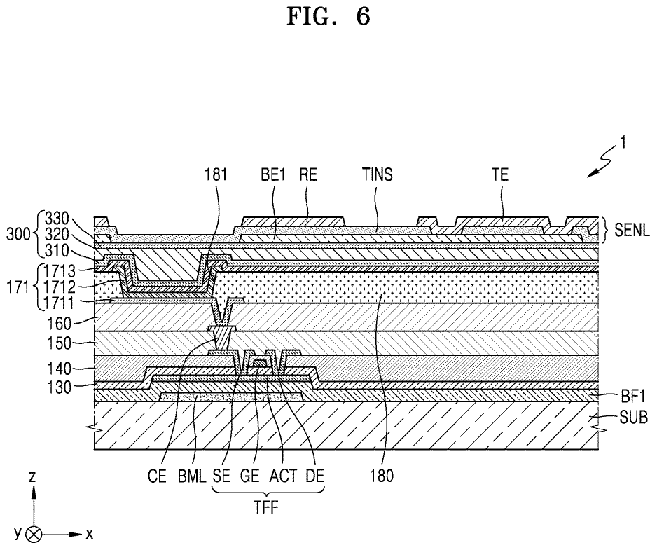

A printed circuit board PSB generates the scan signals, and the scan signals may be transmitted to the scan lines SL. Additionally, the printed circuit board PSB may supply a first power voltage to a first power voltage line 11 (see FIG. 3), and may supply a second power voltage to a second power voltage line 12 (see FIG. 3). Accordingly, the first power voltage line 11 (see FIG. 3) may supply the first power voltage to the light-emitting diode 171 (see FIG. 6), and the second power voltage line 12 (see FIG. 3) may supply the second power voltage to the light-emitting diode 171 (see FIG. 6).

FIG. 3 is a plan view schematically illustrating the display device 1 according to one or more embodiments.

Referring to FIG. 3, the display device 1 includes the substrate SUB. Various components forming the display device 1 are located on the substrate SUB (as used herein, “located on” may mean “above”). The substrate SUB includes the display area DA and the peripheral area PA outside the display area DA. In the specification, when a component is located in the display area DA, it means that the component is located on the display area DA of the substrate SUB or is located to overlap the display area DA of the substrate SUB. Similarly, in this specification, when a component is located in the peripheral area PA, it means that the component is located in the peripheral area PA of the substrate SUB or is located to overlap the peripheral area PA of the substrate SUB.

A plurality of the pixels PX may be located in the display area DA. Each pixel PX may be implemented as a light-emitting diode, such as an organic light-emitting diode. For example, each pixel PX may emit light of red, green, blue, or white.

Pixel circuits driving the pixels PX may be connected to signal lines or voltage lines for controlling on/off and brightness of light-emitting diodes. For example, FIG. 3 illustrates the scan lines SL extending in a first direction (e.g., an x-axis direction) as a signal line, the data lines DL extending in the second direction (e.g., the y-axis direction) and a driving voltage line PL as a voltage line.

The peripheral area PA may be a non-display area that does not display the images. The peripheral area PA may entirely surround the display area DA. The peripheral area PA includes external circuits for driving the pixels PX. For example, a first scan driver SDRV1, a second scan driver SDRV2, the driver DV, a terminal portion PAD, the first power voltage line 11, and the second power voltage line 12 may be located in the peripheral area PA.

The first scan driver SDRV1 may apply the scan signals to each pixel circuit that drives the pixels PX through the scan lines SL. The second scan driver SDRV2 may be located opposite the first scan driver SDRV1 with respect to the display area DA and may be approximately parallel to the first scan driver SDRV1. Some of the pixel circuits of the pixels PX located in the display area DA may be electrically connected to the first scan driver SDRV1, and the rest may be electrically connected to the second scan driver SDRV2.

The driver DV may include an integrated circuit (e.g., a driving chip) that drives the display device 1. The integrated circuit may be the TDDI that generate the data signals and touch drive signals, but the disclosure is not limited thereto.

The terminal portion PAD may be located on one side of the substrate SUB. The terminal portion PAD may not be covered by an insulating layer but may be exposed, and thus may be electrically connected to the printed circuit board PSB.

In one or more embodiments, a controller may be located in the printed circuit board PSB. The controller may generate control signals to be transmitted to the first scan driver SDRV1 and the second scan driver SDRV2. Additionally, the controller may supply the first power voltage to the first power voltage line 11 and the second power voltage to the second power voltage line 12. For example, the first power voltage may be a common voltage ELVSS and the second power voltage may be a driving voltage ELVDD. The common voltage ELVSS is applied to an opposite electrode of the light-emitting diode connected to the first power voltage line 11, and the driving voltage ELVDD may be applied to the pixel circuit of the pixels PX through the driving voltage line PL connected to the second power voltage line 12.

The first power voltage line 11 has a loop shape with one side open, so that the first power voltage line 11 may partially surround the display area DA. The second power voltage line 12 may be provided to extend in the first direction (e.g., the x-axis direction) from the lower side of the display area DA.

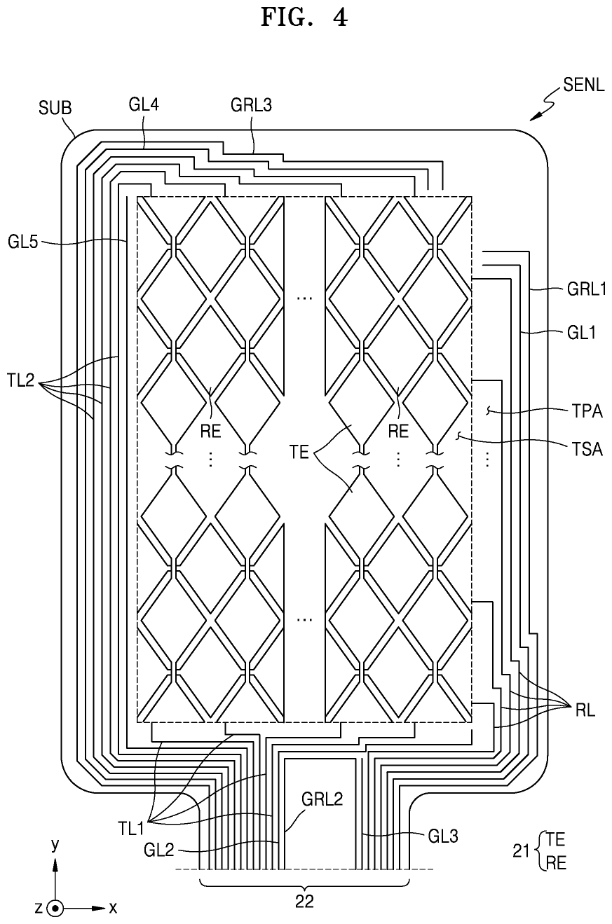

FIG. 4 is a plan view schematically illustrating the touch sensor portion SENL according to one or more embodiments.

In FIG. 4, for convenience of explanation and illustration, only a touch electrode 21, sensor wires TL1, TL2, and RL, guard wires GL1 to GL5, and ground wires GRL1 to GRL3 are illustrated.

Referring to FIG. 4, the touch sensor portion SENL includes a sensor area TSA for detecting the user's touch and a sensor peripheral area TPA located around the sensor area TSA. The substrate SUB includes the display area DA (see FIG. 1) and the peripheral area PA (see FIG. 1) outside the display area, and the sensor area TSA may overlap the display area DA (see FIG. 1) and the sensor peripheral area TPA may overlap the peripheral area PA (see FIG. 1). Obviously, the peripheral area PA (see FIG. 1) outside the display area DA (see FIG. 1) may have a larger area than the sensor peripheral area TPA.

The touch sensor portion SENL may include the touch electrode 21 and a touch-electrode-connecting line (e.g., a touch connecting line) 22. The touch electrode 21 may include the driving electrodes TE and the detection electrodes RE. The touch sensor portion SENL may be driven in a two-layer mutual capacitance manner by applying a driving signal to the driving electrodes TE, and by then detecting the voltages charged in the mutual capacitances through the detection electrodes RE. In FIG. 4, each of the driving electrodes TE and the detection electrodes RE is illustrated as having a rhombus-shaped plane shape, but the disclosure is not limited thereto.

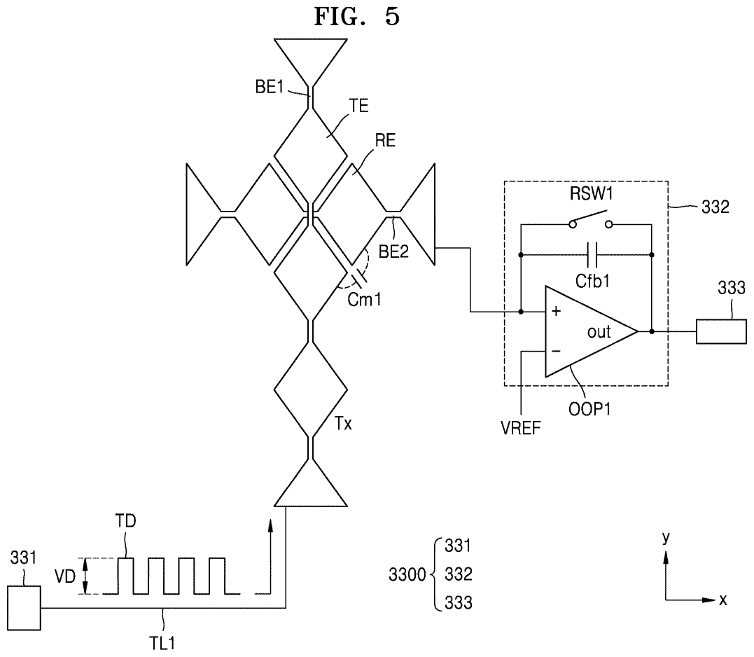

The detection electrodes RE may be located in the first direction (e.g., the x-axis direction), and may be electrically connected to each other. The driving electrodes TE are located in the second direction (e.g., the y-axis direction) crossing the first direction (e.g., the x-axis direction), and may be electrically connected to each other. The driving electrodes TE may be electrically separated from the detection electrodes RE. The driving electrodes TE may be located apart from the detection electrodes RE. For the detection electrodes RE to be electrically separated from the driving electrodes TE in crossing regions thereof, the driving electrodes TE adjacent to each other in the second direction (e.g., the y-axis direction) may be connected to each other through a first connecting portion BE1 (see FIG. 5), and the detection electrodes RE adjacent to each other in the first direction (e.g., the x-axis direction) may be connected to each other through a second connecting portion BE2 (see FIG. 5).

The sensor wires TL1, TL2, and RL may be located in the sensor peripheral area TPA. The sensor wires TL1, TL2, and RL may include detection wires RL connected to the detection electrodes RE, and first driving wires TL1 and second driving wires TL2 connected to the driving electrodes TE.

The detection electrodes RE located on one side of the sensor area TSA may be connected to the detection wires RL. For example, as illustrated in FIG. 4, the detection electrode RE located at the right end may be connected to the detection wire RL.

The driving electrodes TE located on one side of the sensor area TSA may be connected to the first driving wires TL1, and the driving electrodes TE located on another side of the sensor area TSA may be connected to the second driving wires TL2. For example, among the driving electrodes TE electrically connected in the second direction (e.g., the y-axis direction) as illustrated in FIG. 4, the driving electrode TE located at the lower end may be connected to the first driving wire TL1, and the driving electrode TE located at the upper end may be connected to the second driving wire TL2. The second driving wires TL2 may be connected to the driving electrodes TE on the upper side of the sensor area TSA through the left outer side of the sensor area TSA.

A first guard wire GL1 may be located outside the detection wire RL located in the outermost portion among the detection wires RL. In addition, a first ground wire GRL1 may be located outside the first guard wire GL1. As illustrated in FIG. 4, the first guard wire GL1 may be located to the right of the detection wire RL located at the right end among the detection wires RL, and the first ground wire GRL1 may be located to the right of the first guard wire GL1.

A second guard wire GL2 may be located between the detection wire RL located in the innermost portion among the detection wires RL, and the first driving wire TL1 located at the right end among the first driving wires TL1. As illustrated in FIG. 4, the detection wire RL located in the innermost portion among the detection wires RL may be the detection wire RL located at the left end among the detection wires RL. In addition, the second guard wire GL2 may be located between the first driving wire TL1 located at the right end among the first driving wires TL1, and the second ground wire GRL2.

A third guard wire GL3 may be located between the detection wire RL located in the innermost portion among the detection wires RL, and the second ground wire GRL2. A fourth guard wire GL4 may be located outside the second driving wire TL2 located in the outermost portion among the second driving wires TL2. As illustrated in FIG. 4, the fourth guard wire GL4 may be located to the left of the second driving wire TL2 located at the left end among the second driving wires TL2. The third ground wire GRL3 may be located outside the fourth guard wire GL4. As illustrated in FIG. 4, the fourth guard wire GL4 may be located on the left and upper side of the second driving wire TL2 located at the left and upper end of the second driving wires TL2, and the third ground wire GRL3 may be located on the left and upper side of the fourth guard wire GL4.

A fifth guard wire GL5 may be located inside the second driving wire TL2 located in the innermost portion among the second driving wires TL2. As illustrated in FIG. 4, the fifth guard wire GL5 may be located between the second driving wire TL2 located at the right end among the second driving wires TL2 and the detection electrodes RE.

A ground voltage may be applied to the first ground wire GRL1, a second ground wire GRL2, and a third ground wire GRL3. In addition, the ground voltage may be applied to the first guard wire GL1, the second guard wire GL2, the third guard wire GL3, the fourth guard wire GL4, and the fifth guard wire GL5.

As illustrated in FIG. 4, adjacent driving electrodes TE in the second direction (e.g., the y-axis direction) are electrically connected, and adjacent driving electrodes TE in the first direction (e.g., the x-axis direction) are electrically insulated. Additionally, the detection electrodes RE adjacent in the first direction (e.g., the x-axis direction) are electrically connected, and the detection electrodes RE adjacent in the second direction (e.g., the y-axis direction) are electrically insulated. Accordingly, the mutual capacitance may be formed at crossing regions (e.g., intersection points) of the driving electrodes TE and the detection electrodes RE.

In addition, as illustrated in FIG. 4, the first guard wire GL1 is located between the outermost detection wire RL and the first ground wire GRL1, so that the influence of the outermost detection wire RL on the voltage change of the first ground wire GRL1 may be reduced. The second guard wire GL2 is located between the detection wire RL located in the innermost portion and the first driving wire TL1 located in the outermost portion. Accordingly, the influence of a voltage change of the first driving wire TL1 located in the outermost portion on the detection wire RL located in the innermost portion may be reduced.

Because the third guard wire GL3 is located between the detection wire RL located in the innermost portion and the second ground wire GRL2, the detection wire RL located in the innermost portion may be reduced from being influenced by a voltage change of the second ground wire GRL2. Because the fourth guard wire GL4 is located between the second driving wire TL2 located in the outermost portion and the third ground wire GRL3, the second driving wire TL2 may be reduced from being influenced by a voltage change of the third ground wire GRL3. Because the fifth guard wire GL5 is located between the second driving wire TL2 located in the innermost portion and the sensor electrodes TE and RE, the second driving wire TL2 located in the innermost portion and the sensor electrodes TE and RE may be reduced from being influenced by each other.

The touch electrode 21, the sensor wires TL1, TL2, and RL, the guard wires GL1 to GL5, and the ground wires GRL1 to GRL3 may each be electrically connected to the touch-electrode-connecting line 22. For example, a portion of each of the touch electrodes 21, the sensor wires TL1, TL2, and RL, the guard wires GL1 to GL5, and the ground wires GRL1 to GRL3 may form the touch-electrode-connecting line 22. The touch-electrode-connecting line 22 may electrically connect the touch electrode 21 with the driver DV (see FIG. 2).

FIG. 5 is a circuit diagram schematically illustrating a sensor driver 3300 according to one or more embodiments.

For convenience of explanation, in FIG. 5, only the driving electrodes TE located in one column and electrically connected in the second direction (the y-axis direction) and the detection electrodes RE located in one row and electrically connected in the first direction (e.g., the x-axis direction) are illustrated.

Referring to FIGS. 4 and 5, the sensor driver 3300 may include a driving signal output unit 331, a first sensor detection unit 332, and a first analog-to-digital converter 333.

The driving signal output unit 331 may output the touch-driving signal TD to the driving electrodes TE through the first driving wire TL1, and may output the touch-driving signal TD to the driving electrodes TE through the second driving wire TL2. The touch-driving signal TD may include a plurality of pulses each having an amplitude of VD. The driving signal output unit 331 may output touch-driving signals TD to the driving wires TL1 and TL2 in a corresponding order (e.g., a preset order). For example, the driving signal output unit 331 may sequentially output the touch-driving signal TD from the driving electrodes TE located on the left side of the touch sensor area TSA of FIG. 5 to the driving electrodes TE located on the right side of the touch sensor area TSA.

The first sensor detection unit 332 senses a voltage charged in a first mutual capacitance Cm1 through the detection wire RL electrically connected to the detection electrodes RE. As illustrated in FIG. 5, the first mutual capacitance Cm1 may be formed between the driving electrode TE and the detection electrode RE.

The first sensor detection unit 332 may include a first operational amplifier OOP1, a first feedback capacitor Cfb1, and a first reset switch RSW1. The first operational amplifier OOP1 may include a first input terminal “−”, a second input terminal “+”, and an output terminal “out.” The first input terminal “−” of the first operational amplifier OOP1 is connected to the detection wire RL, an initialization voltage VREF is supplied to the second input terminal “+”, and the output terminal “out” of the first operational amplifier OOP1 may be connected to a first storage capacitor. The first storage capacitor is connected between the output terminal “out” of the first operational amplifier OOP1 and ground, and stores an output voltage Vout1 of the first operational amplifier OOP1. The first feedback capacitor Cfb1 and the first reset switch RSW1 may be connected in parallel between the first input terminal “−” and the output terminal “out” of the first operational amplifier OOP1. The first reset switch RSW1 is configured to control connection of two opposite ends of the first feedback capacitor Cfb1. In the case where the first reset switch RSW1 is turned on and the two opposite ends of the first feedback capacitor Cfb1 are connected to each other, the first feedback capacitor Cfb1 may be reset.

The output voltage Vout1 of the first operational amplifier OOP1 may be defined as Vout1=(Cm1×Vt1)/Cfb1. Here, “Cfb1” denotes a capacitance of the first feedback capacitor Cfb1, “Vt1” denotes a voltage charged in the first mutual capacitance Cm1.

The first analog-to-digital converter 333 may convert the output voltage Vout1 stored in the first storage capacitor into first digital data, and may output the first digital data.

As illustrated in FIG. 5, the touch sensor portion SENL may determine whether the user has touched the touch sensor portion by detecting the voltages charged in the first mutual capacitances Cm1.

FIG. 6 is a cross-sectional view schematically illustrating the display device 1 according to one or more embodiments.

For example, FIG. 6 is a drawing illustrating a cross-sectional view of a display panel PNL (see FIG. 2) in the display area DA (see FIG. 2).

The display panel PNL may include the display portion DP and the touch sensor portion SENL. For example, the display portion DP includes the substrate SUB, a first thin film transistor TFT, the light-emitting diode 171, and an encapsulation layer 300, and the touch sensor portion SENL may include the touch electrode 21.

A first buffer layer BF1 located on the substrate SUB may play a role in protecting the first thin film transistor TFT and the light-emitting diode 171 from moisture or the like penetrating through the substrate SUB (as used herein, “located on” may mean “above”). The first buffer layer BF1 may have a single-layer structure or a multi-layer structure. As an example, the first buffer layer BF1 may have a multi-layer structure in which one or more inorganic layers of a silicon nitride layer, a silicon oxynitride layer, a silicon oxide layer, a titanium oxide layer, and an aluminum oxide layer are alternately stacked. Depending on the case, the first buffer layer BF1 may be omitted.

The first thin film transistor TFT may include a semiconductor layer ACT, a gate electrode GE, a source electrode SE, and a drain electrode DE. In FIG. 6, the first thin film transistor TFT is illustrated as a top-gate type thin film transistor in which the gate electrode GE is located on top of the semiconductor layer ACT, but the disclosure is not limited thereto. That is, the first thin film transistor TFT may be a bottom-gate type thin film transistor in which the gate electrode GE is located at the bottom of the semiconductor layer ACT, or may be a double-gate type thin film transistor in which the gate electrode GE is located at both the top and bottom of the semiconductor layer ACT.

The semiconductor layer ACT is located on the first buffer layer BF1. The semiconductor layer ACT may include polycrystalline silicon, single crystal silicon, low temperature polycrystalline silicon, amorphous silicon, or an oxide semiconductor. As an example, the oxide semiconductor may include a two-component-based compound ABₓ, a three-component-based compound ABₓC_{y}, or a four-component-based compound ABₓC_{y}D_{z} including indium, zinc, gallium, tin, titanium, aluminum, hafnium (Hf), zirconium (Zr), or magnesium (Mg). Alternatively, the semiconductor layer ACT may include ITZO (an oxide including indium, tin, and titanium) or IGZO (an oxide including indium, gallium, and tin). A bottom metal layer BML may be located below the semiconductor layer ACT, and the bottom metal layer BML may have a single-layer structure or multi-layer structure including one of an alloy of molybdenum (Mo), aluminum (AI), chromium (Cr), gold (Au), titanium (Ti), nickel (Ni), neodymium (Nd), and/or copper (Cu).

A gate-insulating layer 130 may be located on the semiconductor layer ACT. The gate-insulating layer 130 may include an inorganic layer including silicon nitride, silicon oxynitride, silicon oxide, titanium oxide, or aluminum oxide.

The gate electrode GE may be located on the gate-insulating layer 130. The gate electrode GE may overlap the semiconductor layer ACT. The gate electrode GE and the gate wire may have a single-layer structure or a multi-layer structure including one of an alloy of molybdenum (Mo), aluminum (Al), chromium (Cr), gold (Au), titanium (Ti), nickel (Ni), neodymium (Nd), and/or copper (Cu). For example, the gate electrode GE may have a Mo/Al/Mo structure.

An interlayer insulating layer 140 may be located on the gate electrode GE. The interlayer insulating layer 140 may include an inorganic layer including silicon nitride, silicon oxynitride, silicon oxide, titanium oxide, or aluminum oxide.

The source electrode SE and the drain electrode DE may be located on the interlayer insulating layer 140. The source electrode SE and the drain electrode DE may be located on the gate electrode GE (e.g., may be located at a layer above the gate electrode GE). The source electrode SE and the drain electrode DE may be electrically connected to the semiconductor layer ACT. Each of the source electrode SE and the drain electrode DE may contact the semiconductor layer ACT through a contact hole penetrating the interlayer insulating layer 140. The source electrode SE and the drain electrode DE may have a single-layer structure or a multi-layer structure including one of an alloy of molybdenum (Mo), aluminum (AI), chromium (Cr), gold (Au), titanium (Ti), nickel (Ni), neodymium (Nd), and/or copper (Cu). For example, the source electrode SE and the drain electrode DE may have a Ti/Al/Ti structure.

Obviously, the first thin film transistor TFT does not always have to include both the source electrode SE and the drain electrode DE. For example, when the source region of the semiconductor layer ACT is directly connected to the drain region of the semiconductor layer of another thin film transistor, the first thin film transistor TFT may be modified in various ways, such as not including the source electrode SE. Alternatively, the source electrode SE may be part of another conductive layer that is a different wire.

A first planarization layer 150 may be located on the source electrode SE and the drain electrode DE to planarize a step caused by the first thin film transistor TFT. The first planarization layer 150 may include an insulating organic material, such as acrylic resin, epoxy resin, phenolic resin, polyamide resin, or polyimide resin.

A second planarization layer 160 may be located on the first planarization layer 150. The second planarization layer 160 may include an insulating organic material, such as acrylic resin, epoxy resin, phenolic resin, polyamide resin, or polyimide resin. In addition, when needed, various wires may be located between the first planarization layer 150 and the second planarization layer 160.

A pixel-defining layer 180 may be located on the second planarization layer 160. The light-emitting diode 171 may be an organic light-emitting diode as illustrated in FIG. 6. In this case, the light-emitting diode 171 may include a first pixel electrode 1711, a first intermediate layer 1712 including a first emission layer, and a first opposite electrode 1713.

The first pixel electrode 1711 may be located on the second planarization layer 160. For example, a first connecting electrode CE may be located between the first planarization layer 150 and the second planarization layer 160. The first connecting electrode CE may be located on the source electrode SE and the drain electrode DE. The first connecting electrode CE may electrically connect at least one of the source electrode SE or the drain electrode DE with the light-emitting diode 171.

The first connecting electrode CE may be electrically connected to either the source electrode SE or the drain electrode DE through a contact hole penetrating the first planarization layer 150. The first pixel electrode 1711 may be electrically connected to the first connecting electrode CE through a contact hole penetrating the second planarization layer 160. That is, the first pixel electrode 1711 may be electrically connected to the first thin film transistor TFT. The first connecting electrode CE may have a single-layer structure or a multi-layer structure including one of an alloy of molybdenum (Mo), aluminum (Al), chromium (Cr), gold (Au), titanium (Ti), nickel (Ni), neodymium (Nd), and/or copper (Cu). For example, the first connecting electrode CE may have a Ti/Al/Ti structure.

The first pixel electrode 1711 may include a layer formed of a metal material having a high reflectivity, such as a laminated structure of aluminum and titanium (Ti/Al/Ti), a laminated structure of aluminum and ITO (ITO/AI/ITO), an APC alloy, or a laminated structure of APC alloy and ITO (ITO/APC/ITO). An APC alloy is an alloy including silver (Ag), palladium (Pd), and/or copper (Cu).

The pixel-defining layer 180 has, or defines, a pixel opening 181 that exposes the central portion of the first pixel electrode 1711, and may cover the edges of each of the first pixel electrodes 1711. The pixel-defining layer 180 may include an organic material, such as acrylic resin, epoxy resin, phenolic resin, polyamide resin, and polyimide resin.

The first intermediate layer 1712 including the first emission layer is located on the first pixel electrode 1711 and the pixel-defining layer 180. The first intermediate layer 1712 may include a hole transport layer or an electron transport layer in addition to the first emission layer. The first emission layer included in the first intermediate layer 1712 may have a shape patterned to correspond to the first pixel electrode 1711, as illustrated in FIG. 6. The hole transport layer or the electron transport layer other than the first emission layer may be patterned to correspond to each first pixel electrode 1711 and may have a shape which is one body over other pixel electrodes including the first pixel electrode 1711. In addition, depending on the case, the first emission layer may also have a shape which is one body over the plurality of first pixel electrodes 1711. In this case, a quantum-dot layer and the like including quantum dots serving as a color-converting function may be located on a light path and may implement a full-color display.

The first opposite electrode 1713 is located on the first intermediate layer 1712 including the first emission layer. A capping layer may be formed on the first opposite electrode 1713. The first opposite electrode 1713 may include a transparent conductive material (TCO), such as ITO and IZO that may transmit light, or a semi-transmissive conductive material, such as magnesium (Mg), silver (Ag) or an alloy of magnesium (Mg) and silver (Ag). The first opposite electrode 1713 may have a shape which is one body over the other pixel electrodes as well as the first pixel electrode 1711.

The encapsulation layer 300 is located on the first opposite electrode 1713. The encapsulation layer 300 includes an inorganic layer and an organic layer, and may reduce or prevent oxygen or moisture from penetrating into the first intermediate layer 1712 including the first emission layer and the first opposite electrode 1713. For example, the encapsulation layer 300 may include a first inorganic encapsulation layer 310 located on the first opposite electrode 1713, an organic encapsulation layer 320 located on the first inorganic encapsulation layer 310, and a second inorganic encapsulation layer 330 located on the organic encapsulation layer 320. The first inorganic encapsulation layer 310 and the second inorganic encapsulation layer 330 may include silicon nitride, silicon oxynitride, silicon oxide, titanium oxide, or aluminum oxide. The organic encapsulation layer 320 may include an acrylic resin, an epoxy resin, a phenolic resin, a polyamide resin, a polyimide resin, or the like.

First connecting portions BE1 may be located on the encapsulation layer 300. The first connecting portions BE1 may overlap the pixel-defining layer 180 when viewed in a direction perpendicular to the substrate SUB (e.g., in the z-axis direction). The first connecting portions BE1 may have a stack structure of Ti/Al/Ti including aluminum and titanium, a stack structure of ITO/AI/ITO including aluminum and ITO, an APC alloy, and a stack structure of ITO/APC/ITO including an APC alloy and ITO. However, the present disclosure is not limited thereto.

A sensor insulating layer TINS is located on the first connecting portions BE1. The sensor insulating layer TINS may include an inorganic layer including silicon nitride, silicon oxynitride, silicon oxide, titanium oxide, or aluminum oxide. Alternatively, the sensor insulating layer TINS may include an insulating organic material, such as acrylic resin, epoxy resin, phenolic resin, polyamide resin or polyimide resin.

On the sensor insulating layer TINS, the driving electrodes TE, the detection electrodes RE, the second connecting portions BE2, the first driving wires TL1, the second driving wires TL2, the detection wires RL, the guard wires GL1, GL2, GL3, GL4, and GL5, and the ground wires GRL1, GRL2, and GRL3 described with reference to FIGS. 4 and 5 may be located. The driving electrodes TE, the detection electrodes RE, and the second connecting portion BE2 may overlap the pixel-defining layer 180 when viewed in a direction perpendicular to the substrate SUB (e.g., in the z-axis direction). The driving electrodes TE, the detection electrodes RE, the second connecting portions BE2, the first driving wires TL1, the second driving wires TL2, the detection wires RL, the guard wires GL1, GL2, GL3, GL4, and GL5, and the ground wires GRL1, GRL2, and GRL3 may have a laminated structure of aluminum and titanium (Ti/Al/Ti), a laminated structure of aluminum and ITO (ITO/AI/ITO), an APC alloy, and a laminated structure of APC alloy and ITO (ITO/APC/ITO). However, the present disclosure is not limited thereto. The first driving wires TL1, the second driving wires TL2, and the detection wires RL may be simultaneously formed while the driving electrodes TE and the detection electrodes RE are formed, and may include the same material as that of the driving electrodes TE and the detection electrodes RE.

The sensor insulating layer TINS may include a contact hole CNT passing through the sensor insulating layer TINS and exposing the first connecting portions BE1. The driving electrodes TE may be connected to the first connecting portions BE1 through the contact hole CNT.

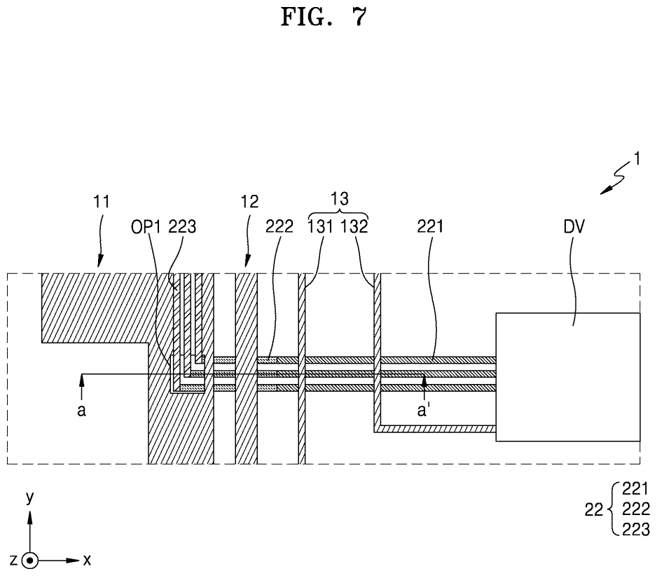

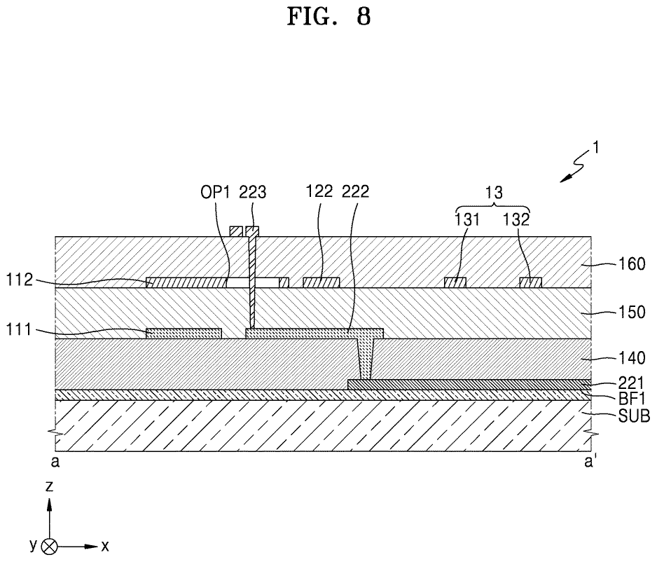

FIG. 7 is a plan view schematically illustrating the display device 1 according to one or more embodiments, and FIG. 8 is a cross-sectional view schematically illustrating the display device 1 according to one or more embodiments.

For example, FIG. 7 is an enlarged view of a part of the display device 1 for area A of FIG. 3, and FIG. 8 is a cross-sectional view of the display device 1 along the line a-a′ of FIG. 7.

Referring to FIGS. 7 and 8, the touch-electrode-connecting line 22 for electrically connecting the touch electrode 21 and the driver DV may include a first connection wire 221, a second connection wire 222, and a third connection wire 223.

The first buffer layer BF1 is located on the substrate SUB (as used herein, “located on” may mean “above”). The first connection wire 221 may be located on the first buffer layer BF1. The interlayer insulating layer 140 may be located on the first buffer layer BF1 to cover the first connection wire 221. The second connection wire 222 and a first-1 power voltage line 111, etc., may be located on the interlayer insulating layer 140. The second connection wire 222 may contact the first connection wire 221 through the contact hole penetrating (e.g., defined by) the interlayer insulating layer 140.

The first planarization layer 150 may be located on the interlayer insulating layer 140 to cover the second connection wire 222 and the first-1 power voltage line 111, etc. A first-2 power voltage line 112, a second-2 power voltage line 122 including (e.g., defining) a first opening OP1, and a signal line 13 including a first signal line 131 and a second signal line 132 may be located on the first planarization layer 150. The second planarization layer 160 may be located on the first planarization layer 150 to cover the first-2 power voltage line 112, the second-2 power voltage line 122, and the signal line 13. The third connection wire 223 may be located on the second planarization layer 160. The third connection wire 223 may contact the second connection wire 222 through the contact hole penetrating the first planarization layer 150, the first opening OP1, and the second planarization layer 160.

In FIG. 7, the first connection wire 221, the second connection wire 222, and the third connection wire 223 are illustrated as being provided as a set of three, but this is only an example, and the number of the first connection wire 221, the second connection wire 222, and the third connection wire 223 is not limited thereto. In addition, in FIGS. 7 and 8, one first signal line 131 and one second signal line 132 are provided respectively, but this is only an example, and the first signal line 131 and the second signal line 132 may be provided as multiples.

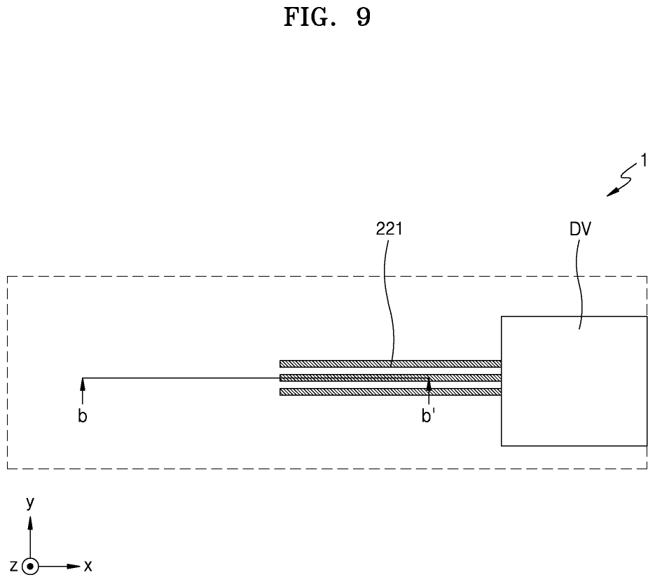

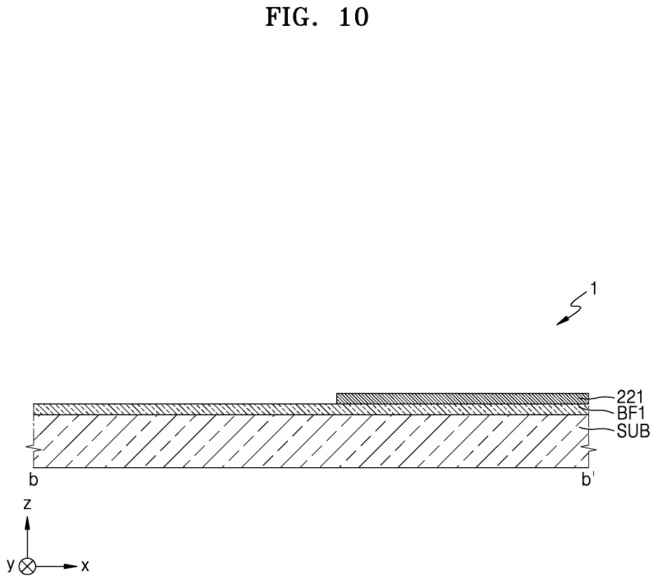

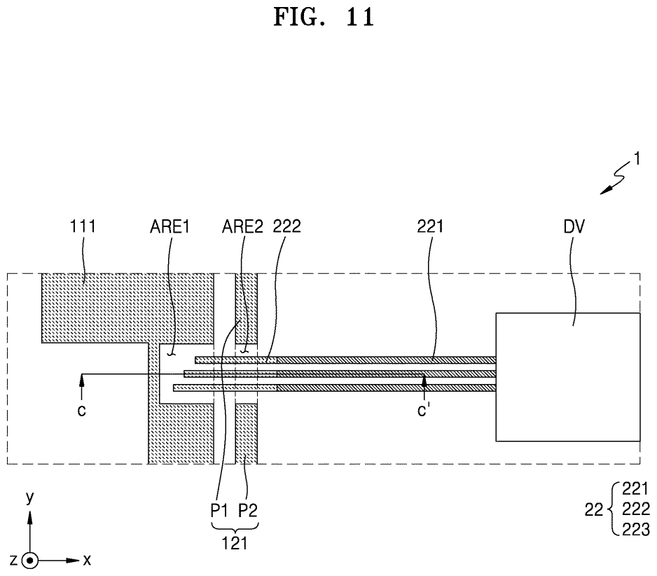

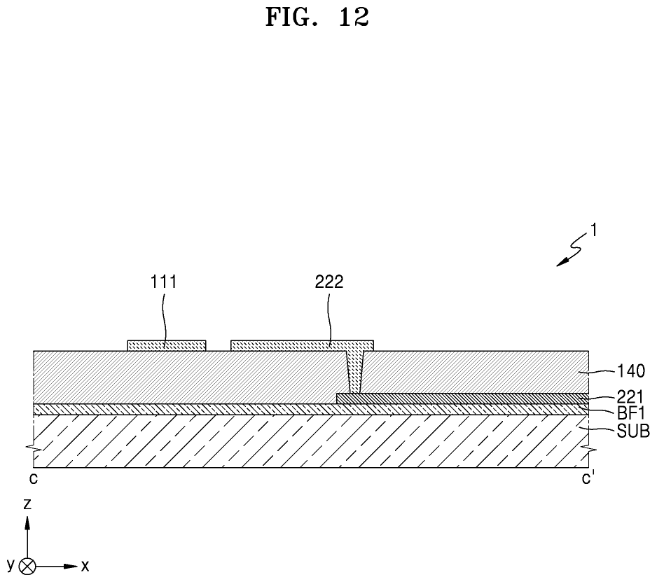

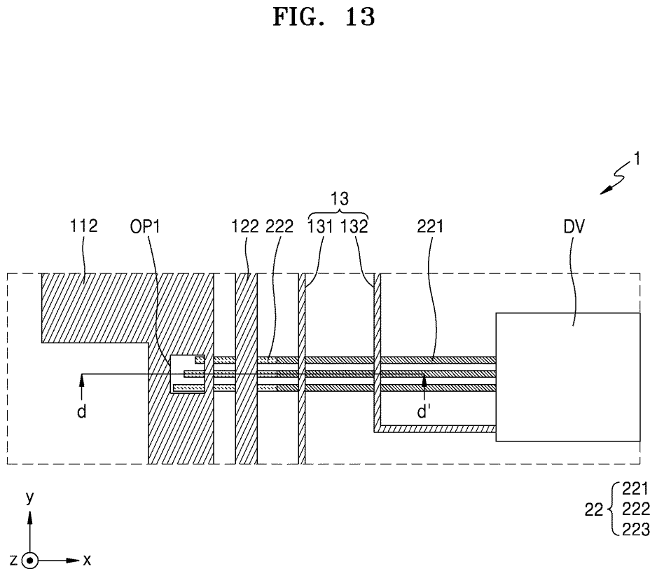

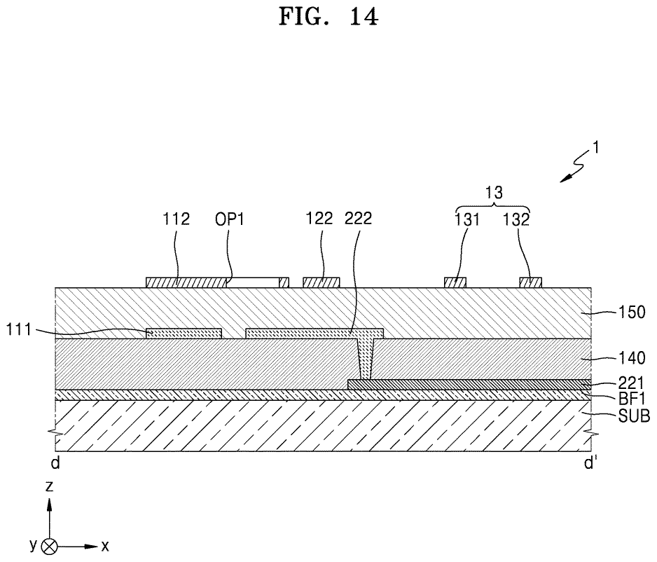

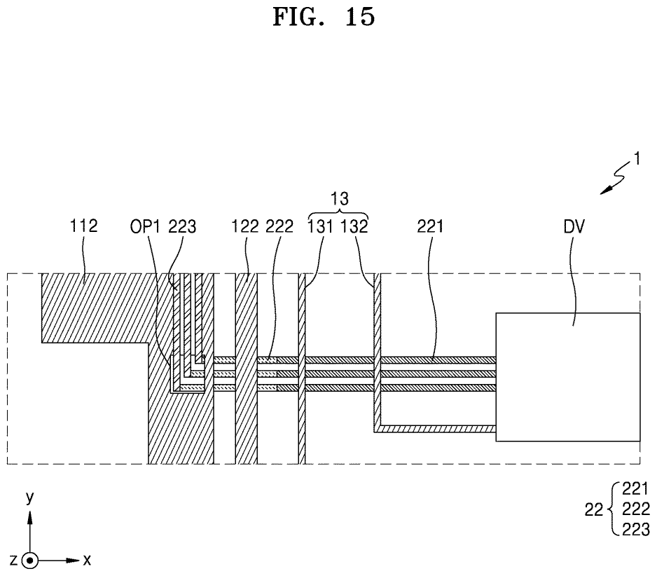

FIG. 9 is a plan view schematically illustrating the display device 1 according to one or more embodiments, FIG. 10 is a cross-sectional view schematically illustrating the display device 1 according to one or more embodiments, FIG. 11 is a plan view schematically illustrating the display device 1 according to one or more embodiments, FIG. 12 is a cross-sectional view schematically illustrating the display device 1 according to one or more embodiments, FIG. 13 is a plan view schematically illustrating the display device 1 according to one or more embodiments, FIG. 14 is a cross-sectional view schematically illustrating the display device 1 according to one or more embodiments, and FIG. 15 is a plan view schematically illustrating the display device 1 according to one or more embodiments.

For example, FIGS. 9, 11, 13, and 15 are enlarged views of a portion of the display device 1 for area A of FIG. 3, FIG. 10 is a cross-sectional view of the display device 1 along the line b-b′ of FIG. 9, FIG. 12 is a cross-sectional view of the display device 1 along the line c-c′ of FIG. 11, and FIG. 14 is a cross-sectional view of the display device 1 along the line d-d′ of FIG. 13.

Referring to FIGS. 9 and 10, the first buffer layer BF1 may be located on the substrate SUB, and the first connection wire 221 may be located on the first buffer layer BF1. The first connection wire 221 extends in the first direction (e.g., the x-axis direction) and may be connected to the driver DV. The first connection wire 221 may include the same material as the gate electrode GE (see FIG. 6), and may be located at the same layer as the gate electrode GE (see FIG. 6). For example, the first connection wire 221 may have a Mo/Al/Mo structure.

Referring to FIGS. 11 and 12, the interlayer insulating layer 140 may be located on the first connection wire 221. The interlayer insulating layer 140 may be located on the first buffer layer BF1 to cover the first connection wire 221. The second connection wire 222, the first-1 power voltage line 111, and a second-1 power voltage line 121 may be located on the interlayer insulating layer 140.

The second connection wire 222 may be located on the first connection wire 221 so as to be connected to the first connection wire 221. The second connection wire 222 may extend in the first direction (e.g., the x-axis direction). The second connection wire 222 may contact the first connection wire 221 through the contact hole penetrating the interlayer insulating layer 140.

The first-1 power voltage line 111 may extend in the second direction (e.g., the y-axis direction), and may be spaced apart from the second connection wire 222. In a plan view, the first-1 power voltage line 111 and the second connection wire 222 may not overlap each other. At least a portion of the first-1 power voltage line 111 may surround the second connection wire 222. The first-1 power voltage line 111 may include a first area ARE1 recessed from one side of the first-1 power voltage line 111. At least a portion of the second connection wire 222 may be located in the first area ARE1.

The second-1 power voltage line 121 extends in the second direction (e.g., the y-axis direction), and may be spaced apart from each of the second connection wire 222 and the first-1 power voltage line 111. The second-1 power voltage line 121 may not overlap (e.g., may be spaced from) the second connection wire 222 and the first-1 power voltage line 111. The second-1 power voltage line 121 may include a first portion P1 and a second portion P2. The first portion P1 and the second portion P2 may be spaced apart from each other with a second area ARE2 therebetween. The second connection wire 222 may cross the second area ARE2. That is, along the second direction (e.g., the y-axis direction), the second portion P2, the second connection wire 222, and the first portion P1 may be sequentially located while being spaced apart from each other.

The second connection wire 222, the first-1 power voltage line 111 and the second-1 power voltage line 121 may include the same material as the source electrode SE (see FIG. 6) and the drain electrode DE (see FIG. 6), and may be located at the same layer as the source electrode SE (see FIG. 6) and the drain electrode DE (see FIG. 6). For example, the second connection wire 222, the first-1 power voltage line 111, and the second-1 power voltage line 121 may have a Ti/Al/Ti structure.

Referring to FIG. 13 and FIG. 14, the first planarization layer 150 may be located on the second connection wire 222, the first-1 power voltage line 111, and the second-1 power voltage line 121. The first planarization layer 150 may be located on the interlayer insulating layer 140 to cover the second connection wire 222, the first-1 power voltage line 111, and the second-1 power voltage line 121. A first-2 power voltage line 112, the second-2 power voltage line 122, and a signal line 13 may be located on the first planarization layer 150.

The first-2 power voltage line 112 extends in the second direction (e.g., the y-axis direction), and may be located on the first-1 power voltage line 111 so as to be electrically connected to the first-1 power voltage line 111. At least a portion of the first-2 power voltage line 112 may overlap the first-1 power voltage line 111. In one or more embodiments, the first-2 power voltage line 112 may contact the first-1 power voltage line 111 through the contact hole formed in the first planarization layer 150. The first-2 power voltage line 112 may include the first opening OP1. In a plan view, the first opening OP1 may overlap the second connection wire 222. The first-1 power voltage line 111 and the first-2 power voltage line 112 may form the first power voltage line 11 (see FIG. 3). That is, the first power voltage line 11 (see FIG. 3) may include the first-1 power voltage line 111 and a first-2 power voltage line 112.

The second-2 power voltage line 122 extends in the second direction (e.g., the y-axis direction), and may be located on the second-1 power voltage line 121 so as to be electrically connected to the second-1 power voltage line 121. At least a portion of the second-2 power voltage line 122 may overlap the second-1 power voltage line 121. In one or more embodiments, the second-2 power voltage line 122 may contact the second-1 power voltage line 121 through the contact hole formed in the first planarization layer 150. At least a portion of the second-2 power voltage line 122 may overlap the second connection wire 222. The second-1 power voltage line 121 and the second-2 power voltage line 122 may form the second power voltage line 12 (see FIG. 3). That is, the second power voltage line 12 (see FIG. 3) may include the second-1 power voltage line 121 and the second-2 power voltage line 122.

The signal line 13 may extend in the second direction (e.g., the y-axis direction). The signal line 13 may supply at least one of the scan signals or the data signals to the light-emitting diode 171 (see FIG. 6). For example, the signal line 13 may include the first signal line 131 that supplies the scan signals to the light-emitting diode 171 (see FIG. 6), and the second signal line 132 that supplies the data signals to the light-emitting diode 171 (see FIG. 6). The first signal line 131 may be connected to the scan lines SL (see FIG. 3), and the second signal line 132 may be connected to the data lines DL (see FIG. 3).

The first-2 power voltage line 112, the second-2 power voltage line 122, and the signal line 13 may be spaced apart from each other. The first-2 power voltage line 112, the second-2 power voltage line 122, and the signal line 13 may include the same material as the first connecting electrode CE (see FIG. 6), and may be located at the same layer as the first connecting electrode CE (see FIG. 6). For example, the first-2 power voltage line 112, the second-2 power voltage line 122, and the signal line 13 may have a Ti/Al/Ti structure.

Referring to FIG. 15 and FIG. 8, the second planarization layer 160 may be located on the first-2 power voltage line 112, the second-2 power voltage line 122, and the signal line 13. The second planarization layer 160 may be located on the first planarization layer 150 to cover the first-2 power voltage line 112, the second-2 power voltage line 122, and the signal line 13. The third connection wire 223 may be located on the second planarization layer 160.

The third connection wire 223 extends in the second direction (e.g., the y-axis direction), and may connect the second connection wire 222 with the touch electrode 21. The third connection wire 223 may be connected to the second connection wire 222 through the first opening OP1. At least a portion of the third connection wire 223 may overlap the first power voltage line 11 (see FIG. 3). The third connection wire 223 may include the same material as the gate electrode GE (see FIG. 6), and may be located at the same layer as the gate electrode GE (see FIG. 6). For example, the third connection wire 223 may have a Ti/Al/Ti structure.

The first connection wire 221 includes a Mo material, and the second connection wire 222 includes a Ti/Al/Ti structure, so the resistance of the second connection wire 222 may be less than the resistance of the first connection wire 221. Accordingly, because the second connection wire 222 connects the first connection wire 221 with the third connection wire 223, the resistance of the touch-electrode-connecting line 22 may be reduced compared to the case where the first connection wire 221 is directly connected to the third connection wire 223. Therefore, the detection performance of the touch sensor portion SENL may be improved.

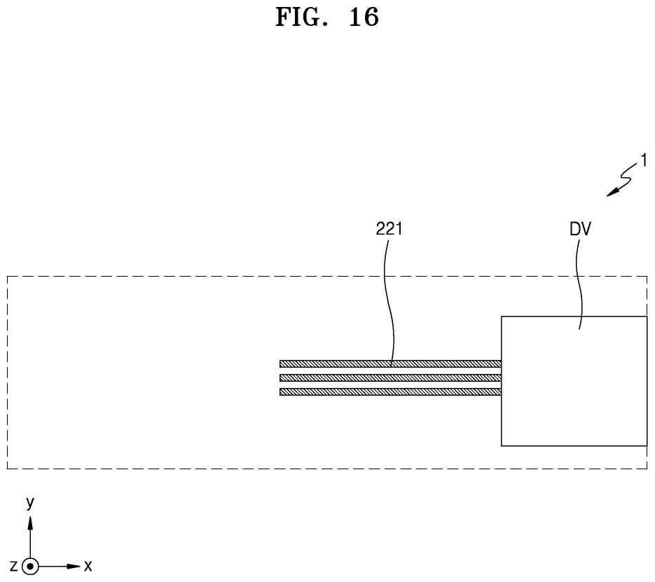

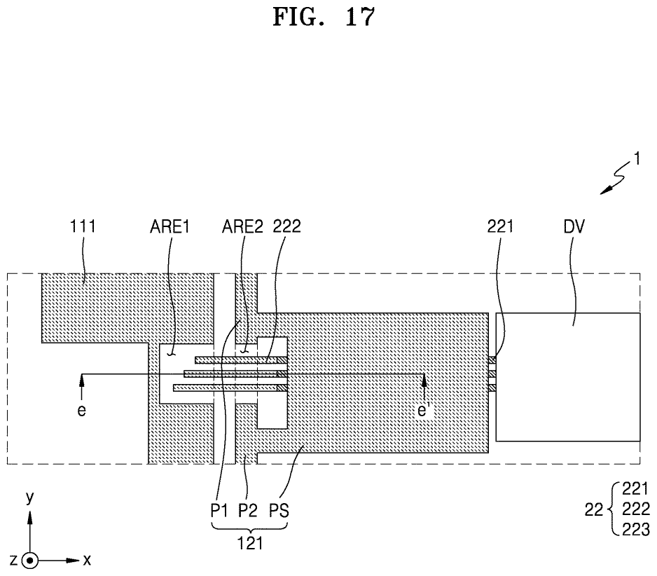

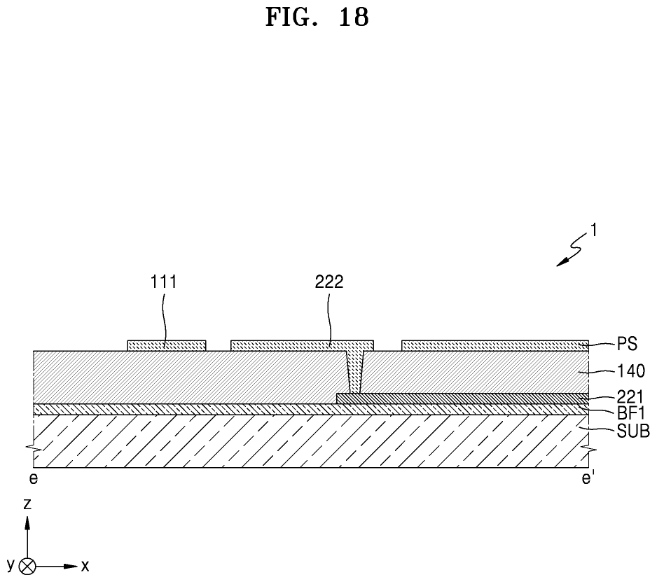

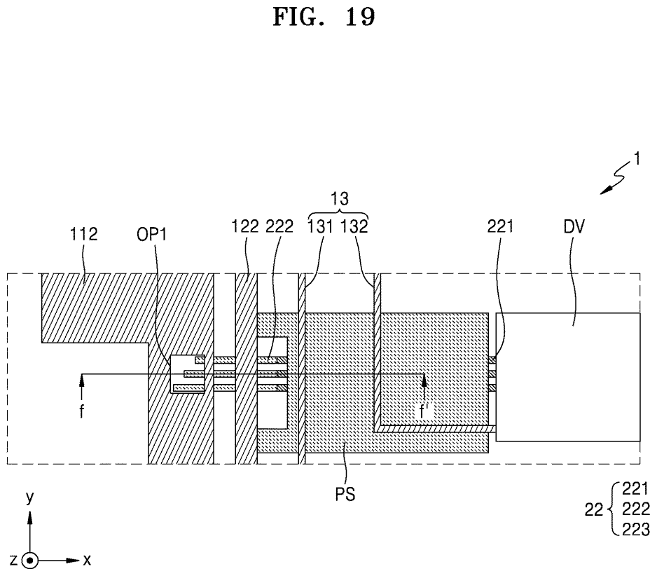

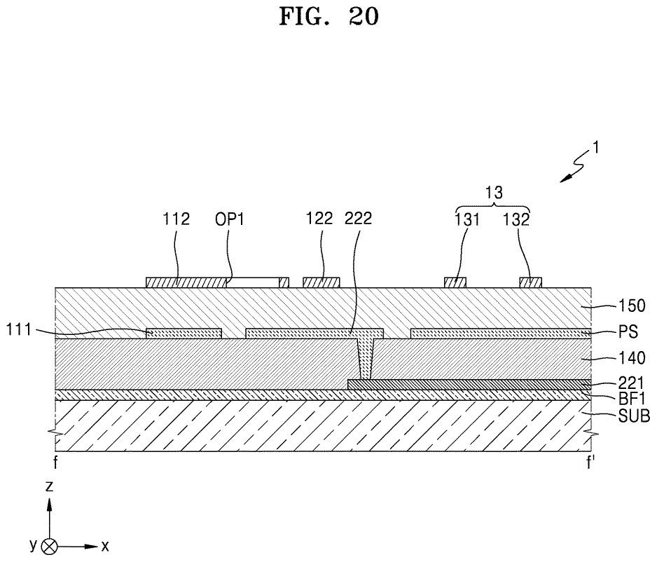

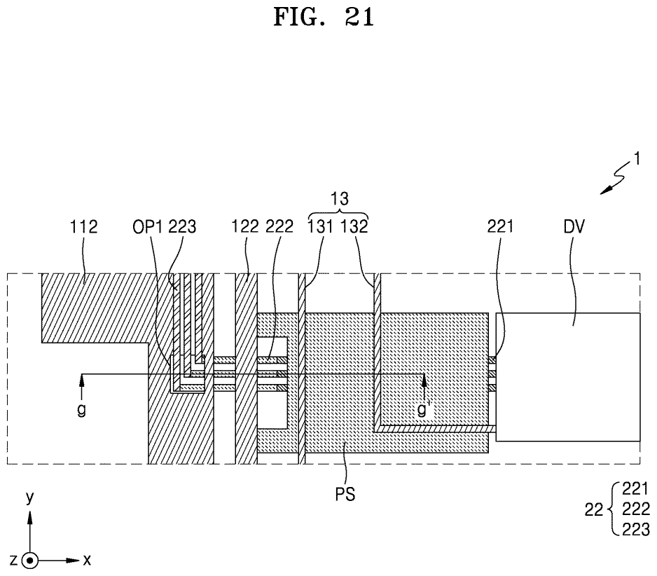

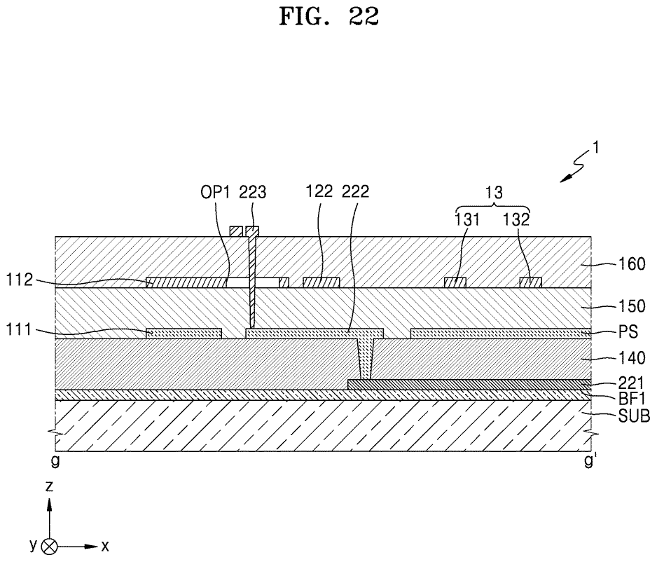

FIG. 16 is a plan view schematically illustrating the display device 1 according to one or more embodiments, FIG. 17 is a plan view schematically illustrating the display device 1 according to one or more embodiments, FIG. 18 is a cross-sectional view schematically illustrating the display device 1 according to one or more embodiments, FIG. 19 is a plan view schematically illustrating the display device 1 according to one or more embodiments, FIG. 20 is a cross-sectional view schematically illustrating the display device 1 according to one or more embodiments, FIG. 21 is a plan view schematically illustrating the display device 1 according to one or more embodiments, and FIG. 22 is a cross-sectional view schematically illustrating the display device 1 according to one or more embodiments.

For example, FIGS. 16, 17, 19, and 21 are enlarged views of a portion of the display device 1 for area A of FIG. 3, FIG. 18 is a cross-sectional view of the display device 1 along the line e-e′ of FIG. 17, FIG. 20 is a cross-sectional view of the display device 1 along the line f-f′ of FIG. 19, and FIG. 22 is a cross-sectional view of the display device 1 along the line g-g′ of FIG. 21.

In FIGS. 16 to 22, the same reference numerals as in FIGS. 7 to 15 designate the same elements, and any redundant description is omitted.

Referring to FIG. 16, the first connection wire 221 extends in the first direction (e.g., the x-axis direction) and may be connected to the driver DV. The first connection wire 221 may include the same material as the gate electrode GE (see FIG. 6), and may be located at the same layer as the gate electrode GE (see FIG. 6).

Referring to FIGS. 17 and 18, the interlayer insulating layer 140 may be located on the first connection wire 221. The first buffer layer BF1 is located on the substrate SUB, and the interlayer insulating layer 140 may be located on the first buffer layer BF1 to cover the first connection wire 221. The second connection wire 222, the first-1 power voltage line 111, and the second-1 power voltage line 121 may be located on the interlayer insulating layer 140.

The second connection wire 222 may be located on the first connection wire 221 so as to be connected to the first connection wire 221. The second connection wire 222 may extend in the first direction (e.g., the x-axis direction). The second connection wire 222 may contact the first connection wire 221 through the contact hole penetrating the interlayer insulating layer 140.

The first-1 power voltage line 111 may extend in the second direction (e.g., the y-axis direction) and may be spaced apart from the second connection wire 222. In a plan view, the first-1 power voltage line 111 and the second connection wire 222 may not overlap each other. At least a portion of the first-1 power voltage line 111 may surround the second connection wire 222. The first-1 power voltage line 111 may include the first area ARE1 recessed from one side of the first-1 power voltage line 111. At least a portion of the second connection wire 222 may be located in the first area ARE1.

The second-1 power voltage line 121 extends in the second direction (e.g., the y-axis direction), and may be spaced apart from each of the second connection wire 222 and the first-1 power voltage line 111. The second-1 power voltage line 121 may not overlap the second connection wire 222 and the first-1 power voltage line 111.

The second-1 power voltage line 121 may include the first portion P1, the second portion P2, and a shield portion PS. The first portion P1 and the second portion P2 may be spaced apart from each other with the second area ARE2 therebetween. The second connection wire 222 may cross the second area ARE2. That is, along the second direction (e.g., the y-axis direction), the second portion P2, the second connection wire 222, and the first portion P1 may be sequentially located while being spaced apart from each other.

The shield portion PS may be connected to each of the first portion P1 and the second portion P2. The shield portion PS may overlap at least partly with the first connection wire 221. However, because the shield portion PS is located at the same layer as the second connection wire 222, the shield portion PS may not overlap the second connection wire 222. That is, along the first direction (e.g., the x-axis direction), the first-1 power voltage line 111, the second connection wire 222, and the shield portion PS may be sequentially located while being spaced apart from each other.

The second connection wire 222, the first-1 power voltage line 111 and the second-1 power voltage line 121 may include the same material as the source electrode SE (see FIG. 6) and the drain electrode DE (see FIG. 6), and may be located at the same layer as the source electrode SE (see FIG. 6) and the drain electrode DE (see FIG. 6). For example, the second connection wire 222, the first-1 power voltage line 111, and the second-1 power voltage line 121 may have a Ti/Al/Ti structure.

Referring to FIGS. 19 and 20, the first planarization layer 150 may be located on the second connection wire 222, the first-1 power voltage line 111, and the second-1 power voltage line 121. The first planarization layer 150 may be located on the interlayer insulating layer 140 to cover the second connection wire 222, the first-1 power voltage line 111, and the second-1 power voltage line 121. A first-2 power voltage line 112, the second-2 power voltage line 122, and the signal line 13 may be located on the first planarization layer 150.

The first-2 power voltage line 112 extends in the second direction (e.g., the y-axis direction), and may be located on the first-1 power voltage line 111 so as to be electrically connected to the first-1 power voltage line 111. At least a portion of the first-2 power voltage line 112 may overlap the first-1 power voltage line 111. The first-2 power voltage line 112 may include the first opening OP1. The first-1 power voltage line 111 and the first-2 power voltage line 112 may form the first power voltage line 11 (see FIG. 3). That is, the first power voltage line 11 (see FIG. 3) may include the first-1 power voltage line 111 and a first-2 power voltage line 112.

The second-2 power voltage line 122 extends in the second direction (e.g., the y-axis direction), and may be located on the second-1 power voltage line 121 so as to be electrically connected to the second-1 power voltage line 121. At least a portion of the second-2 power voltage line 122 may overlap the second-1 power voltage line 121. At least a portion of the second-2 power voltage line 122 may overlap the second connection wire 222. The second-1 power voltage line 121 and the second-2 power voltage line 122 may form the second power voltage line 12 (see FIG. 3). That is, the second power voltage line 12 (see FIG. 3) may include the second-1 power voltage line 121 and the second-2 power voltage line 122.

The signal line 13 may extend in the second direction (e.g., the y-axis direction). The signal line 13 may supply at least one of the scan signals or the data signals to the light-emitting diode 171 (see FIG. 6). For example, the signal line 13 may include the first signal line 131 that supplies the scan signals to the light-emitting diode 171 (see FIG. 6), and the second signal line 132 that supplies the data signals to the light-emitting diode 171 (see FIG. 6).

The shield portion PS may be located between the first connection wire 221 and the signal line 13. The shield portion PS may shield noise generated from the signal line 13. Accordingly, the shield portion PS may reduce the phenomenon of noise generated in the signal line 13 being transmitted to the first connection wire 221. Therefore, the detection performance of the touch sensor portion SENL may be improved.

The first-2 power voltage line 112, the second-2 power voltage line 122 and the signal line 13 may be spaced apart from each other. The first-2 power voltage line 112, the second-2 power voltage line 122 and the signal line 13 may include the same material as the first connecting electrode CE (see FIG. 6), and may be located at the same layer as the first connecting electrode CE (see FIG. 6).

Referring to FIGS. 21 and 22, the second planarization layer 160 may be located on the first-2 power voltage line 112, the second-2 power voltage line 122, and the signal line 13. The second planarization layer 160 may be located on the first planarization layer 150 to cover the first-2 power voltage line 112, the second-2 power voltage line 122, and the signal line 13. The third connection wire 223 may be located on the second planarization layer 160.

The third connection wire 223 extends in the second direction (e.g., the y-axis direction), and may connect the second connection wire 222 with the touch electrode 21. The third connection wire 223 may be connected to the second connection wire 222 through the first opening OP1. At least a portion of the third connection wire 223 may overlap the first power voltage line 11 (see FIG. 3). The third connection wire 223 may include the same material as the gate electrode GE (see FIG. 6) and may be located at the same layer as the gate electrode GE (see FIG. 6).

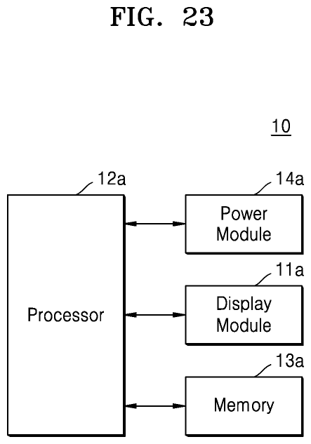

FIG. 23 is a block diagram schematically illustrating an electronic device 10 according to one or more embodiments.

Referring to FIG. 23, the electronic device 10 according to one or more embodiments may include a display module 11a, a processor 12a, a memory 13a, and a power module 14a.

The processor 12a may include at least one of a central processing unit (CPU), an application processor (AP), a graphics processing unit (GPU), a communication processor (CP), an image signal processor (ISP), or a controller. The processor 12a may include at least one of a central processing unit (CPU), an application processor (AP), a graphic processing unit (GPU), a communication processor (CP), an image signal processor (ISP), or a controller.

Data information necessary for the operation of the processor 12a or the display module 11a may be stored in the memory 13a. When the processor 12a executes an application stored in the memory 13a, an image the data signals and/or an input control signal is transmitted to the display module 11a, and the display module 11a may process the received signal, and may output image information through a display screen.

The power module 14a may include a power supply module, such as a power adapter or a battery device, and a power conversion module that converts power supplied by the power supply module to generate power required for the operation of the electronic device 10.

At least one of the components of the above-described electronic device 10 may be included in the display device according to the above-described embodiments. Additionally, some of the individual modules functionally included within a module may be included within the display device, while others may be provided separately from the display device. For example, the display device may include the display module 11a, and the processor 12a, memory 13a, and power module 14a may be provided in the form of other devices within the electronic device 10 other than the display device.

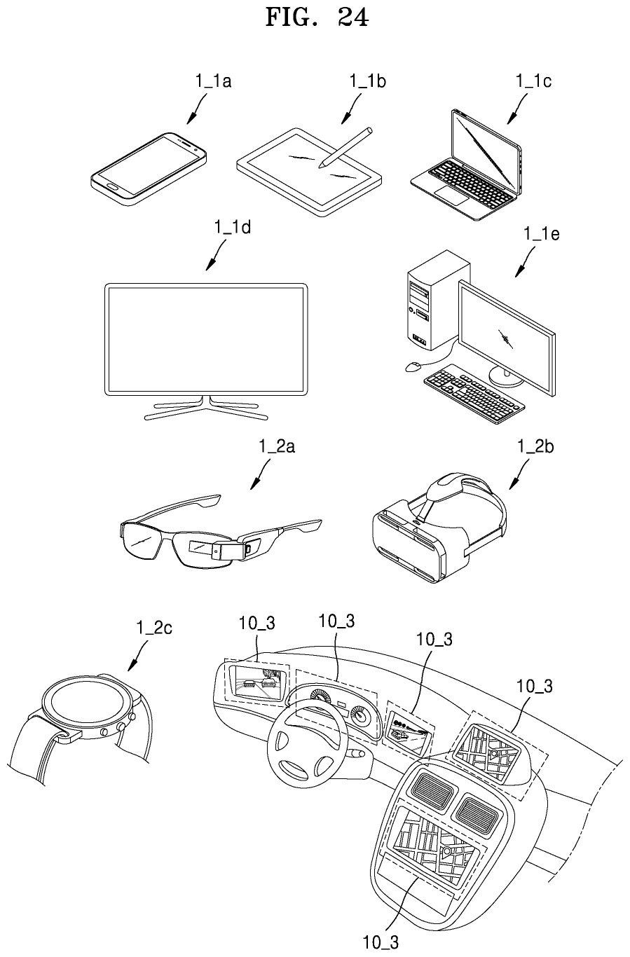

FIG. 24 is a perspective view schematically illustrating the electronic device according to one or more embodiments.

Referring to FIG. 24, various electronic devices to which display devices according to embodiments are applied may include not only image display electronic devices, such as a smart phone 1_1a, a tablet PC 1_1b, a laptop 1_1c, a TV 1_1d, and a desk monitor 1_1e, but also wearable electronic devices including display modules, such as smart glasses 1_2a, a head mounted display 1_2b, and a smart watch 1_2c, and vehicle electronic devices 10_3 including display modules, such as a center information display (CID) and a room mirror display located on a dashboard, center fascia, and dashboard of an automobile.

According to embodiments, the performance of the touch sensor portion may be improved.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a display panel comprising a display portion, and a touch sensor portion above the display portion; and
a driver configured to drive the display portion and the touch sensor portion,
wherein the display portion comprises:
a light-emitting diode;
a first power voltage line configured to supply a first power voltage to the light-emitting diode; and
a second power voltage line configured to supply a second power voltage to the light-emitting diode,
wherein the touch sensor portion comprises:
a touch electrode; and
a touch-electrode-connecting line electrically connecting the touch electrode with the driver, and comprising:
a first connection wire connected to the driver;
a second connection wire above the first connection wire, and connected to the first connection wire; and
a third connection wire above the first power voltage line and the second connection wire, and connecting the second connection wire with the touch electrode.

2. The display device of claim 1, wherein the first power voltage line comprises:
a first-1 power voltage line at a same layer as the second connection wire, and spaced apart from the second connection wire; and
a first-2 power voltage line above the first-1 power voltage line and electrically connected to the first-1 power voltage line.

3. The display device of claim 2, wherein the third connection wire is above the first-2 power voltage line, and has a portion overlapping the first power voltage line.

4. The display device of claim 3, wherein the first-2 power voltage line defines a first opening, and
wherein the third connection wire is connected to the second connection wire through the first opening.

5. The display device of claim 1, wherein the second power voltage line comprises:
a second-1 power voltage line at a same layer as the second connection wire, and spaced apart from the second connection wire; and
a second-2 power voltage line above the second-1 power voltage line and electrically connected to the second-1 power voltage line.

6. The display device of claim 5, wherein the second-1 power voltage line comprises a shield portion at least partially overlapping the first connection wire.

7. The display device of claim 6, wherein the display portion further comprises a signal line configured to supply at least one of a scan signal or a data signal to the light-emitting diode, at a same layer as the second-2 power voltage line, and having a portion overlapping the shield portion.

8. The display device of claim 5, wherein a portion of the second-2 power voltage line overlaps the second connection wire.

9. The display device of claim 1, wherein the display portion further comprises:
a semiconductor layer;
a gate electrode above the semiconductor layer;
a source electrode and a drain electrode at a layer above the gate electrode, and electrically connected to the semiconductor layer; and
a first connecting electrode at a layer above the source electrode and the drain electrode, and electrically connecting the source electrode or the drain electrode with the light-emitting diode.

10. The display device of claim 9, wherein the gate electrode and the first connection wire comprise a same material, and are at a same layer, and
wherein the source electrode, the drain electrode, and the second connection wire comprise a same material, and are at a same layer.

11. An electronic device comprising:
a display panel comprising a display portion, and a touch sensor portion above the display portion; and
a driver configured to drive the display portion and the touch sensor portion,
wherein the display portion comprises:
a semiconductor layer;
a gate electrode above the semiconductor layer;
a source electrode and a drain electrode at a layer above the gate electrode, and electrically connected to the semiconductor layer;
a first connecting electrode at a layer above the source electrode and the drain electrode, and electrically connected to the source electrode or the drain electrode;
a light-emitting diode above the first connecting electrode, and electrically connected to the first connecting electrode;
a first power voltage line configured to supply a first power voltage to the light-emitting diode; and
a second power voltage line configured to supply a second power voltage to the light-emitting diode,
wherein the touch sensor portion comprises:
a touch electrode; and
a touch-electrode-connecting line electrically connecting the touch electrode with the driver, and comprising:
a first connection wire connected to the driver and at a same layer as the gate electrode;
a second connection wire connected to the first connection wire and at a same layer as the source electrode and the drain electrode; and
a third connection wire above the second connection wire and connecting the second connection wire with the touch electrode.

12. The electronic device of claim 11, wherein the third connection wire is above the first power voltage line and the second power voltage line.

13. The electronic device of claim 12, wherein the first power voltage line comprises:
a first-1 power voltage line at a same layer as the second connection wire, and spaced apart from the second connection wire; and
a first-2 power voltage line above the first-1 power voltage line and electrically connected to the first-1 power voltage line.

14. The electronic device of claim 13, wherein the third connection wire is above the first-2 power voltage line, and
wherein a portion of the third connection wire overlaps the first power voltage line.

15. The electronic device of claim 14, wherein the first-2 power voltage line defines a first opening overlapping the second connection wire.

16. The electronic device of claim 15, wherein the third connection wire is connected to the second connection wire through the first opening.

17. The electronic device of claim 11, wherein the second power voltage line comprises:
a second-1 power voltage line at a same layer as the second connection wire, and spaced apart from the second connection wire, and
a second-2 power voltage line above the second-1 power voltage line and electrically connected to the second-1 power voltage line.

18. The electronic device of claim 17, wherein the second-1 power voltage line comprises a shield portion at least partially overlapping the first connection wire.

19. The electronic device of claim 18, wherein the display portion further comprises a signal line configured to supply at least one of a scan signal or a data signal to the light-emitting diode, a same layer as the second-2 power voltage line, and having a portion overlapping the shield portion.

20. The electronic device of claim 17, wherein a portion of the second-2 power voltage line overlaps the second connection wire.
